(19) United States
(12) Patent Application Publication
(10) Pub. No.: US 2007/0084546 A1
(43) Pub. Date: Apr. 19, 2007

(54) Method and apparatus for colorant transfer

(76) Inventor: Charles E. Contompasis, Schenectady, NY (US)

Correspondence Address: HESLIN ROTHENBERG FARLEY & MESITI PC, 5 COLUMBIA CIRCLE, ALBANY, NY, 12203, US

(21) Appl. No.: 11/253,386

(22) Filed: Oct. 19, 2005

(51) Int. Cl. B05D 3/00; B44C 1/165; B44C 1/175; C23C 14/00

(52) U.S. Cl. 156/230; 427/294; 156/236; 156/285; 156/240; 118/50

(57) ABSTRACT

An image is created on a substrate capable of, or made capable of (e.g., coating with a thickener), accepting colorant. In one example, the image is printed onto the coated substrate using an inkjet printer. Porous material, for example, clothing or plaster, is treated with a dissolvent for dissolving the thickener. Contacting the treated porous material with the imaged substrate causes the thickener to dissolve. A chemical activator for activating the colorant may also be used (e.g., in the coating or by pretreatment). Under vacuum, the colorant of the image is drawn from the substrate to the porous material without using heat.

### BACKGROUND OF THE INVENTION

1. Technical Field

The present invention generally relates to image transfer. More particularly, the present invention relates to image transfer by transferring colorant from a substrate to a porous material without using heat.

2. Background Information

In the past and still today, patterns are created in porous materials, such as fabric for clothing, by hand, by processes such as imprinting, stenciling, silk screening, dyeing, transfer, ink jet, tie dye, etc., and more recently by automated methods. Each has drawbacks and limitations. For example, creating fabric designs by hand (e.g., by ink application), by tie dye or by silk screening is time consuming and relatively low-volume producing. As another example, imprinting, stenciling and other similar methods place the exact same design on all the fabric created, resulting in a lack of uniqueness in the finished product, which may not be desirable for some applications. As still a further example, silk screening allows for no variation, is a relatively expensive pattern-creation technique, only allows the application of one color per screen, and provides only limited penetration of colorant through fabric.

Various approaches have evolved to increase the volume of porous material imaging, most notably in the textile industry. For example, heat transfer of a rubberized image has been used. However, such images have typically not been considered of high quality, and often break down after repeated washings, for example. Direct printing on fabric has also been used. Direct printing is typically either done on continuous fabric rolls using a rotary screen continuous process system, or using specially designed ink-jet printers. Methods of stabilizing the fabric have been developed that allow the printing nozzles to be presented thereto. However, while both methods increase the volume of imaging, continuous systems, for example, do not allow for any variation of design in the end product. While fabric ink jets do provide the full capabilities of digital imaging, both methods are very expensive to implement, due to the difficulties of dimensionally stabilizing the fabric for printing, as well as the equipment, expertise and effort involved in preparing the fabric, e.g., controlling PH, ink flow, bleeding and penetration.

Thus, a need continues to exist for a relatively simple, cost-effective way to image porous material quickly.

### SUMMARY OF THE INVENTION

Briefly, the present invention satisfies the need for a relatively simple, cost-effective way to image porous material quickly, by providing a substrate capable or made capable (via a coating) of accepting colorant. Such a substrate with colorant is contacted with porous material, pretreated to facilitate transfer in the case of no coating, and the colorant is drawn via vacuum from the substrate to the porous material without using heat.

In accordance with the above, it is an object of the present invention to provide a way to image porous material.

It is another object of the present invention to provide a substrate for colorant transfer from the substrate to porous material.

It is yet another object of the present invention to provide a relatively simple way to transfer colorant from a substrate to porous material without using heat.

It is still another object of the present invention to provide a way to image porous materials with digital images.

The present invention provides, in a first aspect, a method of colorant transfer. The method comprises obtaining a substrate with a coating and a colorant thereon, the coating comprising a thickener for holding the colorant. The method also comprises dissolving the thickener, causing the substrate and a porous material to come into contact, and drawing the colorant via vacuum from the substrate to the porous material without using heat.

The present invention provides, in a second aspect, a method of image transfer. The method comprises obtaining a substrate coated with a thickener, and creating an image on the coated substrate, the image comprising a colorant. The method also comprises dissolving the thickener, causing the imaged substrate and a porous material to come into contact, and drawing the colorant of the image via vacuum from the substrate to the porous material without using heat.

The present invention provides, in a third aspect, apparatus for colorant transfer. The apparatus comprises a substrate with a coating thereon, the coating comprising a thickener for holding colorant when applied thereto, and means for drawing colorant when present from the substrate to a porous material when present without using heat.

The present invention provides, in a fourth aspect, a method of colorant transfer. The method comprises obtaining a substrate without a coating for holding colorant, the substrate having a colorant thereon. The method also comprises pretreating a porous material to facilitate transfer of the colorant, causing the substrate and the porous material to come into contact, and drawing the colorant via vacuum from the substrate to the porous material without using heat.

The present invention provides, in a fifth aspect, a method of image transfer. The method comprises obtaining a substrate without a coating for holding colorant, creating an image on the substrate, the image comprising a colorant. The method also comprises pretreating a porous material to facilitate transfer of the colorant, causing the imaged substrate to come into contact with the pretreated porous material, and drawing the colorant of the image via vacuum from the substrate to the pretreated porous material without using heat.

The present invention provides, in a sixth aspect, apparatus for colorant transfer. The apparatus comprises a substrate without a coating for holding colorant, and being capable of holding colorant. The apparatus also comprises means for pretreating a porous material to facilitate colorant transfer, and means for drawing colorant when present from the substrate to a porous material when present without using heat.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 depicts a coated substrate with colorant coming into contact with a treated porous material in an atmosphere flow, in accordance with the present invention.

FIG. 2 depicts a substrate and porous material similar to FIG. 1 within a vacuum chamber (partial break-away view of chamber) to create the atmosphere flow.

FIG. 3 depicts an ink jet printer creating an image on a coated substrate, in accordance with the present invention.

### DETAILED DESCRIPTION OF THE INVENTION

The present invention is well-suited to custom designs, trials of designs, and unique digital designs to name just a few, and competes favorably with textile inkjet printing. In addition, expense is greatly decreased for labor set-up time and material costs. Further, the technique lends itself to use with a variety of shapes of fabric, for example, traditional panels, pre-cut shapes for assembly into a garment, and whole, finished garments. The technique also provides a quick response, measured in minutes, rather than hours or weeks; it beats traditional methods and even betters known digital imaging, since there is no extensive preparation or stabilization needed.

The present invention provides an imaging transfer technique that is simple, relatively inexpensive and results in final images of high quality. In one example, a colorant-accepting substrate coated with a thickener for holding the colorant and a chemical activator that, when released by dissolving the thickener, activates the colorant. An image can be created on the coated substrate, for example, by use of an ink-jet printer, allowing for digital imaging. Dissolving of the thickener is accomplished, for example, by pretreating porous material with a dissolvent for the thickener, and bringing the imaged substrate into contact therewith in an atmosphere flow to draw the colorant.

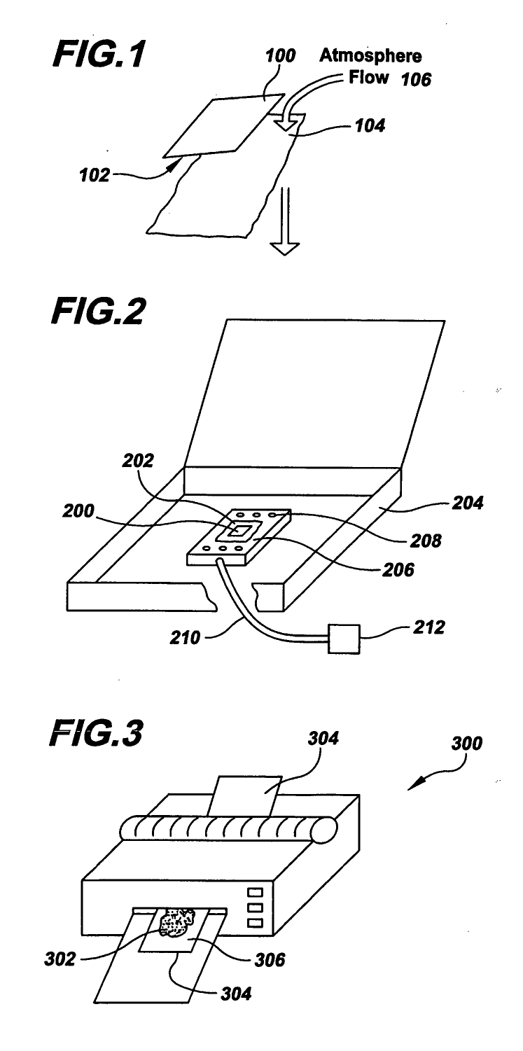

FIG. 1 depicts a substrate 100 having on its face 102 a colorant and, optionally, a coating. The coating, when present, comprises a thickener for holding colorant and, optionally, a chemical activator for the colorant. A porous material 104 is, for example, pretreated with a dissolvent for dissolving the thickener on the substrate. Where a chemical activator is used, instead of including a chemical activator in the coating, for example, pretreating the porous material alone with a chemical activator could instead be done. In addition, as one skilled in the art will know, pigment-based dyes include a binder in the dye, such that no auxiliary chemical activator is needed, though one could still be used as a “booster” for colorant transfer. Water may also be combined with the dissolvent, or, in some cases, may actually be the dissolvent. The dissolvent dissolves the thickener by, for example, transforming it from a dry film to a viscous liquid film. A chemical activator for the colorant may also be added to the dissolvent pretreatment. As the substrate and porous material are brought into contact, the dissolvent dissolves the thickener (e.g., by rehydration) to the point where the chemical activator, when used, is able to activate the colorant. In another example, the thickener begins dissolving prior to contact with the porous material. In that case, the porous material need not be pretreated, but can be to further ensure a high-quality transfer. In either case, an atmosphere flow 106 draws the colorant from the substrate to the porous material.

In the case where the thickener begins dissolving prior to contact with the porous material, the dissolvent is applied to the coated substrate after colorant. In one example, where the thickener is guar gum, dissolving is accomplished by rehydration by, for example, applying a layer of liquid guar gum, diluted gum or water by silkscreen or other coating method such as spray mist. Of course, rehydrating the thickener also allows any chemical activator present to begin activating the colorant. Although no longer solid, the thickener, activator and colorant can typically still be placed on the porous material image-down, as shown in FIG. 1. Where the thickener begins dissolving prior to contact with the porous material, pretreating the porous material may not be necessary, though it could still be done to ensure proper transfer.

Although described above with a thickener for holding the colorant, the preferred method, the substrate need not include a thickener or coating, so long as the substrate can itself adequately hold colorant for the particular application. This will depend of course on a number of factors, for example, porosity of the substrate, the colorant to be used, the porous material being used for the transfer, the stability of the substrate after the colorant is applied, and the level of migration of the colorant on the substrate, to name but a few. For example, paper could be used without a thickener or other coating. However, where no coating is present, it is preferred to appropriately pretreat the porous material, for example, with an appropriate chemical activator to activate the colorant or otherwise facilitate the transfer. As noted above, pigment-based dyes do not require an auxiliary chemical activator. Thus, in that case, the pretreatment could be water alone to facilitate the transfer.

The porous material can be anything porous (soft, hard or in between) and capable of accepting colorant transfer. For example, various types of fabric for clothing, or canvas-type material for hats, bags, etc. can be used. As another example, plaster, gypsum board, smooth concrete and similar materials could be used. Further, the porous material can be unfinished, fully finished or partially finished. The substrate comprises, for example, paper, plastic film, polyester film, Polyvinyl Alcohol (PVA), or cellulose. While many different thickeners could be used, the thickener is preferably water based, rehydratable, capable of absorbing the ink of interest, rather than spreading, in a particular application, at least semisolid at the working temperature, and generally having an antimigratory rheology. Examples of thickeners that work with the present invention include guar gum, alginate and PVA.

The chemical activator comprises, for example, an acidifier, an alkalinizer or a polymer binder. The chemical activator works similar to a binder, and helps facilitate the colorant becoming sufficiently affixed to the porous material for the particular application. In other words, the chemical activator enhances colorant/image transfer. The particular chemical activator used will depend on the type of ink used, as well as the porous material that will be used. In addition, as noted previously, pigment-based dyes include a binder in the dye. Thus, as used herein, the term “chemical activator” includes both chemical activators and binders, whether part of the colorant or separate. For example, an acid-based dye is typically used with nylon, silk and wool, which requires an acid pH in the fabric for accepting the acid-based dye. In that situation, the chemical activator would be an acidifier. As another example, a fiber-reactive dye is typically used with cotton, requiring an alkaline pH in the fabric. In that case, the chemical activator would be an alkalinizer. In either case (acidifier or alkalinizer), a polymer binder may also be used for the fixing of pigment colors to the above-noted types of porous materials, or other synthetic fabrics or blends. The polymer binder allows the pigment to act somewhat like paint in terms of surface adherence. As still another example, sublimation inks are typically used with polyester materials, and they also transfer to plastics without the need for auxiliary chemical activators.

The dissolvent comprises, for example, a liquid. The particular dissolvent used will depend on the thickener used. For example, where the thickener is water-based, water can be used as the dissolvent.

Various methods of applying the constituents of the coating to the substrate can be used. For example, where the coating comprises both a thickener and a chemical activator for the colorant, the thickener and chemical activator can be mixed together and applied. Examples of known application methods for liquefied gums include silk screening, atomized or pressure spraying, or using roller bars, magnetic rods, or blades.

Optionally, the thickener can include solid colorant or “dyestuff” to provide a solid background color for the image transfer. Doing so can be more economical than, for example, ink-jet printing (see below) a large area of a solid color. Similarly, the pretreating solution for the porous material can include dyestuff that would color the entire surface of the porous material prior to imaging.

In the special case of PVA, it can function as both substrate and thickener, since it is stable enough to be handled and have colorant applied to it. The PVA is dimensionally stable and not supported on a backing material. The PVA (Polyvinyl alcohol) is water soluble. It is printed with solvent-based ink that does not re-wet or dissolve the film. The solvent-based image is supported on the PVA, and transfers by re-hydration as it does with the other coated substrates. The solvent-based image is transferred and, since there is no backing, the PVA dissolves. In any case, PVA is clear and colorless, and should not be apparent on the porous material.

FIG. 2 depicts a coated and imaged substrate 200 image facing down on pretreated porous material 202 similar to FIG. 1, except within a sealable vacuum chamber 204 to create the atmosphere flow. The porous material may be pretreated with a chemical activator for the particular colorant present in the image on the substrate. The porous material lies on a medium through which atmosphere can flow to the desired amount. In the present example, the medium comprises a hollow template 206. Other examples of the medium include a perforated board or plate, a porous or felted pad, a screen, or some combination of the above. The template is connected via conduit 210 to a vacuum pump 212. The vacuum pump draws atmosphere through openings (e.g., opening 208) in the template. The atmosphere flow serves to hold the substrate firmly against the porous material and draw the image from the substrate to porous material. Preferably, the sealable vacuum chamber is rigid enough to prevent collapse from the atmosphere flow created by the vacuum pump.

U.S. Pat. Nos. 6,655,271 and 6,802,249, by the same inventor as the present invention, include examples of a chamber and templates that could be used with the present invention. The noted patents focus on intentional migration of colorant across and into the porous material for a random design, whereas the present invention focuses on reproduction of an image. Both patents are incorporated herein by reference in their entirety. In addition, the colorant pattern creation ability possible with those systems can be used in tandem with the image transfer method of the present invention, either before or after image transfer. With clothing, for example, doing so would provide an overall “finished” look to the garment.

Optionally, the vacuum chamber can be used, prior to a transfer cycle, to extract moisture (pretreatment) from the porous material in order to reach a desired level. In such an arrangement, the vacuum pump can take the form of a valved vacuum regulator to automatedly achieve the preferred level of moisture in the porous material.

It will be understood that the rigid sealable vacuum chamber described herein is just one example of how to provide an atmosphere flow. Other ways to provide an atmosphere flow include, for example, using a non-rigid vacuum chamber. One example of a non-rigid vacuum chamber is a vacuum bag, sealable with an outlet to a vacuum source. The atmosphere-flow medium and variations thereof described above with respect to FIG. 2 can be used with the non-rigid vacuum chamber.

The image to be transferred can be created on the coated substrate in a number of different ways. For example, colorant could be applied by hand. As another example, silk screening can be used. However, the image is preferably created using an ink-jet printer. If coupled to a computer, for example, the full capabilities of digital imaging are available to refine the image and control color for printing. FIG. 3 depicts an ink jet printer 300 creating an image 302 on a substrate 304 with a coating 306 of a thickener and chemical activator. Of course, the ink jet can also be used to print on a substrate without a coating as well. Where an inkjet is used, special textile inks are typically needed. Such inks are commercially available and often used with ink jets made to print directly on fabric.

The textile inks can be put in a wide range of refillable ink cartridges for ink jets. No special printer is needed to print on the coated substrates. Of course, higher end machines could also be used, such as wide format, sheet feed and roll feed machines. Such machines offer an expanded printing capability and typically an expanded color gamut for more subtle color differences.

All of the various inks noted in the present application are currently commercially available from at least two sources: DuPont, Wilmington, Del.; and Ciba Specialty Chemicals, Charlotte, N.C.

Although the image transfer techniques described herein do not require heat, it will be understood that for all colorant types mentioned, post-transfer treatment may be necessary for fixation of the colorant on the porous material, e.g., using steam, pressurized steam or heat, depending on the particular porous material used and the intended end use.

While several aspects of the present invention have been described and depicted herein, alternative aspects may be effected by those skilled in the art to accomplish the same objectives. For example, the steps or operations described herein may be performed in a different order, unless otherwise specified, or may be added, deleted or modified. Accordingly, it is intended by the appended claims to cover all such alternative aspects as fall within the true spirit and scope of the invention.

1. A method of colorant transfer, comprising:
obtaining a substrate with a coating and a colorant thereon, wherein the coating comprises a thickener for holding the colorant;
dissolving the thickener;
causing the substrate and a porous material to come into contact; and
drawing the colorant via vacuum from the substrate to the porous material without using heat.

2. The method of claim 1, wherein the substrate comprises at least one of paper, plastic film, polyester film, Polyvinyl Alcohol (PVA), and cellulose.

3. The method of claim 1, wherein the thickener comprises at least one of guar gum, alginate, and PVA.

4. The method of claim 3, wherein the substrate and the thickener comprise PVA.

5. The method of claim 1, wherein the coating further comprises a chemical activator for activating the colorant upon dissolving of the thickener.

6. The method of claim 1, further comprising activating the colorant with a chemical activator.

7. The method of claim 1, wherein the chemical activator comprises one of an acidifier, an alkalinizer, and a polymer binder.

8. The method of claim 1, wherein the dissolving is accomplished by pretreating the porous material with dissolvent prior to the contact, and wherein the contact causes the thickener to dissolve.

9. The method of claim 8, further comprising pretreating the porous material with a chemical activator for enhancing transfer of the colorant.

10. The method of claim 8, wherein the thickener is water soluble, and wherein the treating comprises wetting the porous material with water.

11. The method of claim 10, wherein the wetting comprises wetting the porous material with a solution comprising water and a chemical activator for enhancing transfer of the colorant.

12. The method of claim 1, wherein the drawing is performed in a vacuum chamber.

13. The method of claim 1, wherein the colorant comprises a plurality of colors.

14. The method of claim 1, wherein the colorant comprises an image.

15. The method of claim 14, wherein the coating comprises a background colorant for the image.

16. The method of claim 1, wherein the colorant comprises a solid color.

17. The method of claim 1, wherein the obtaining comprises creating an image on the substrate with the colorant.

18. The method of claim 1, wherein the dissolving comprises applying a dissolvent to the thickener.

19. A method of image transfer, comprising:
obtaining a substrate coated with a thickener;
creating an image on the coated substrate, wherein the image comprises a colorant;
dissolving the thickener;
causing the imaged substrate to come into contact with a porous material; and
drawing the colorant of the image via vacuum from the substrate to the porous material without using heat.

20. The method of claim 19, wherein the creating comprises ink-jet printing.

21. The method of claim 19, wherein the substrate comprises at least one of paper, plastic film, polyester film, Polyvinyl Alcohol (PVA), and cellulose.

22. The method of claim 19, wherein the thickener comprises at least one of guar gum, alginate, and PVA.

23. The method of claim 22, wherein the substrate and the thickener comprise PVA.

24. The method of claim 19, wherein the coating further comprises a chemical activator for activating the colorant.

25. The method of claim 19, further comprising activating the colorant with a chemical activator.

26. The method of claim 25, wherein the chemical activator comprises one of an acidifier, an alkalinizer, and a polymer binder.

27. The method of claim 19, wherein the thickener is water soluble, wherein the dissolving is accomplished by pretreating the porous material with dissolvent prior to the contact, and wherein the pretreating comprises wetting the porous material with water.

28. The method of claim 27, wherein the wetting comprises wetting the porous material with a solution comprising water and a chemical activator for activating the colorant.

29. The method of claim 19, wherein the drawing is performed in a vacuum chamber.

30. The method of claim 19, wherein the colorant comprises a plurality of colors.

31. The method of claim 19, wherein the thickener comprises a background colorant for the image.

32. The method of claim 19, wherein the colorant comprises a solid color.

33. The method of claim 19, wherein the dissolving is accomplished by pretreating the porous material with dissolvent prior to the contact, and wherein the contact causes the thickener to dissolve.

34. The method of claim 33, further comprising pretreating the porous material with a chemical activator for activating the colorant, the activating being accomplished by the contact.

35. The method of claim 19, wherein the dissolving comprises applying a dissolvent to the thickener.

36. Apparatus for colorant transfer, comprising:
a substrate with a coating thereon, wherein the coating comprises a thickener for holding colorant when applied thereto; and
means for drawing colorant when present from the substrate to a porous material when present without using heat.

37. The apparatus of claim 36, further comprising an ink jet printer for applying colorant to the coated substrate.

38. The apparatus of claim 36, wherein the substrate further comprises a colorant.

39. The apparatus of claim 38, wherein the colorant comprises an image.

40. The apparatus of claim 38, wherein the colorant comprises a solid color.

41. The apparatus of claim 36, further comprising a dissolvent for dissolving the thickener.

42. The apparatus of claim 41, wherein the dissolvent comprises a solution.

43. The apparatus of claim 42, wherein the solution comprises a chemical activator for activating colorant.

44. The apparatus of claim 36, wherein the substrate comprises at least one of paper, plastic film, polyester film, Polyvinyl Alcohol (PVA), and cellulose.

45. The apparatus of claim 36, wherein the thickener comprises at least one of guar gum, alginate, and PVA.

46. The apparatus of claim 45, wherein the substrate and the thickener comprise PVA.

47. The apparatus of claim 36, wherein the coating further comprises a chemical activator for activating the colorant when present.

48. The apparatus of claim 47, wherein the chemical activator comprises one of an acidifier, an alkalinizer, and a polymer binder.

49. The apparatus of claim 36, further comprising colorant for applying to the substrate.

50. The apparatus of claim 36, further comprising a medium for supporting the porous material when present within the drawing means, wherein the medium is capable of atmosphere flow therethough.

51. The apparatus of claim 36, wherein the drawing means comprises a vacuum chamber.

52. A method of colorant transfer, comprising:
obtaining a substrate without a coating for holding colorant, the substrate having a colorant thereon;
pretreating a porous material to facilitate transfer of the colorant;
causing the substrate and the porous material to come into contact; and
drawing the colorant via vacuum from the substrate to the porous material without using heat.

53. The method of claim 52, wherein the substrate comprises paper.

54. The method of claim 52, wherein the pretreating comprises pretreating with a chemical activator comprising one of an acidifier, an alkalinizer, and a polymer binder.

55. The method of claim 52, wherein the drawing is performed in a vacuum chamber.

56. The method of claim 52, wherein the colorant comprises a plurality of colors.

57. The method of claim 52, wherein the colorant comprises an image.

58. The method of claim 57, wherein the colorant comprises a background colorant for the image.

59. The method of claim 52, wherein the colorant comprises a solid color.

60. The method of claim 52, wherein the obtaining comprises creating an image on the substrate with the colorant.

61. The method of claim 52, wherein the colorant does not require an auxiliary chemical activator, and wherein the pretreating comprises pretreating with water.

62. A method of image transfer, comprising:
obtaining a substrate without a coating for holding colorant;
creating an image on the substrate, wherein the image comprises a colorant;
pretreating a porous material to facilitate transfer of the colorant;
causing the imaged substrate to come into contact with the pretreated porous material; and
drawing the colorant of the image via vacuum from the substrate to the pretreated porous material without using heat.

63. The method of claim 62, wherein the substrate comprises paper.

64. The method of claim 62, wherein the creating comprises ink-jet printing.

65. The method of claim 62, wherein the pretreating comprises pretreating with a chemical activator comprising one of an acidifier, an alkalinizer, and a polymer binder.

66. The method of claim 62, wherein the drawing is performed in a vacuum chamber.

67. The method of claim 62, wherein the colorant comprises a plurality of colors.

68. The method of claim 62, wherein the colorant comprises a background colorant for the image.

69. The method of claim 62, wherein the colorant comprises a solid color.

70. The method of claim 62, wherein the colorant does not require an auxiliary chemical activator, and wherein the pretreating comprises pretreating with water.

71. Apparatus for colorant transfer, comprising:
a substrate without a coating for holding colorant, the substrate being capable of holding colorant;
means for pretreating a porous material to facilitate colorant transfer; and
means for drawing colorant when present from the substrate to a porous material when present without using heat.

72. The apparatus of claim 71, further comprising an ink jet printer for applying colorant to the substrate.

73. The apparatus of claim 71, wherein the substrate comprises paper.

74. The apparatus of claim 71, wherein the substrate further comprises a colorant.

75. The apparatus of claim 74, wherein the colorant comprises an image.

76. The apparatus of claim 74, wherein the colorant comprises a solid color.

77. The apparatus of claim 71, wherein the means for pretreating comprises a chemical activator comprising one of an acidifier, an alkalinizer, and a polymer binder.

78. The apparatus of claim 71, further comprising colorant for applying to the substrate.

79. The apparatus of claim 71, further comprising a medium for supporting the porous material when present within the drawing means, wherein the medium is capable of atmosphere flow therethough.

80. The apparatus of claim 71, wherein the drawing means comprises a vacuum chamber.

81. The apparatus of claim 71, wherein the means for pretreating comprises water.
